(19) United States
(12) Patent Application Publication
(10) Pub. No.: US 2025/0351515 A1
(43) Pub. Date: Nov. 13, 2025

(54) HIGH ELECTRON MOBILITY TRANSISTOR AND MANUFACTURING METHOD OF THE SAME

(71) Applicant: ELECTRONICS AND TELECOMMUNICATIONS RESEARCH INSTITUTE, Daejeon (KR)

(72) Inventors: Hyunwook JUNG, Daejeon (KR); Dohyun KIM, Daejeon (KR); Seong-il KIM, Daejeon (KR); Haecheon KIM, Daejeon (KR); Sang Woo NAM, Daejeon (KR); Youn Sub NOH, Daejeon (KR); Hokyun AHN, Daejeon (KR); Sang-Heung LEE, Daejeon (KR); Jong-Won LIM, Daejeon (KR); Sungjae CHANG, Daejeon (KR); ILGYU CHOI, Daejeon (KR)

(73) Assignee: ELECTRONICS AND TELECOMMUNICATIONS RESEARCH INSTITUTE, Daejeon (KR)

(21) Appl. No.: 18/921,794

(22) Filed: Oct. 21, 2024

(30) Foreign Application Priority Data
May 13, 2024 (KR) 10-2024-0062442

(51) Int. Cl. H01L 29/40; H01L 29/20; H01L 29/423; H01L 29/66; H01L 29/778

(52) U.S. Cl. CPC H10D 64/118; H10D 30/015; H10D 30/475; H10D 62/8503; H10D 64/01; H10D 64/411

(57) ABSTRACT

Provided is a high electron mobility transistor and a manufacturing method of the same. The high electron mobility transistor includes a semiconductor layer on a substrate, a source electrode and a drain electrode on both sides of the semiconductor layer, a gate electrode provided on the semiconductor layer between the source electrode and the drain electrode, and a dielectric block surrounding a bottom of the gate electrode.

### CROSS-REFERENCE TO RELATED APPLICATIONS

This U.S. non-provisional patent application claims priority under 35 U.S.C. § 119 of Korean Patent Application No. 10-2024-0062442, filed on May 13, 2024, the entire contents of which are hereby incorporated by reference.

### BACKGROUND

The present disclosure herein relates to a transistor and a manufacturing method of the same, and more specifically, to a high electron mobility transistor and a manufacturing method of the same.

A high electron mobility transistor has a wide bandgap and high electron saturation rate, and it is necessary to manufacture a semiconductor device that has excellent high-frequency characteristics and high power density due to the high charge concentration and fast mobility of a two-dimensional electron gas (2DEG) semiconductor layer formed during AlGaN/GaN heterojunction. Over the past few years, with the advancement of device scaling technology, frequency characteristics of a nitride-based high electron mobility transistor has been improved. However, a short channel effect that occurs as the semiconductor device is scaled reduces the drain current controllability and deteriorates the frequency characteristics. Therefore, in order to further improve the frequency characteristics, manufacturing techniques other than the device scaling are needed.

A gate length scaling technology is the key to manufacturing a transistor with improved frequency characteristics. The cutoff frequency f_{T} can be increased by increasing the electron movement velocity by shortening a gate length. In addition, the maximum resonance frequency fₘₐₓ can be increased by increasing an area of an upper part of a gate electrode and reducing a resistance of the gate electrode. However, as an area of the upper part of the gate electrode increases, parasitic capacitance between the upper part of the gate electrode and the 2DEG semiconductor layer increases. To solve this, a T-type gate structure, in which the upper part of the gate electrode is spaced apart from the 2DEG semiconductor layer so as to be positioned vertically high, is applied to the transistor.

However, as a channel length becomes shorter in order to increase the frequency characteristics, the parasitic capacitance (fringing capacitance) component occurring between a lower part of the gate electrode and the 2DEG semiconductor layer becomes dominant, and this becomes a factor that impedes the frequency characteristics. Also, due to structural instability where the wide upper part of the gate should be supported by the narrow lower part of the gate, it is difficult to further make the upper gate electrode apart from the semiconductor layer.

### SUMMARY

The present disclosure provides a high electron mobility transistor capable of reducing the parasitic capacitance and fringing capacitance due to reduction in gate length.

An embodiment of the inventive concept discloses a high electron mobility transistor. The high electron mobility transistor includes a semiconductor layer on a substrate, a source electrode and a drain electrode on both sides of the semiconductor layer, a gate electrode provided on the semiconductor layer between the source electrode and the drain electrode, and a dielectric block surrounding a bottom of the gate electrode.

In an embodiment, the dielectric block may include a lower dielectric block and an upper dielectric block provided on the lower dielectric block.

In an embodiment, the lower dielectric block may be wider than the upper dielectric block.

In an embodiment, the high electron mobility transistor may further include a gate pad provided on the gate electrode. The gate electrode may have a width equal to a width of the gate pad between the lower dielectric block and the upper dielectric block.

In an embodiment, the high electron mobility transistor may further include cavity filters provided on the dielectric block.

In an embodiment, the cavity filters may include an external cavity filter surrounding the dielectric block and the gate pad, and the internal cavity filter provided within the external cavity filter.

In an embodiment, each of the external cavity filter and the internal cavity filter may have a square ring shape.

In an embodiment, the external cavity filter may be higher or thicker than the internal cavity filter.

In an embodiment, the internal cavity filter may be provided between the gate pad and the dielectric block.

In an embodiment, the high electron mobility transistor may further include a protection film between the dielectric block and the semiconductor layer.

In an embodiment of the inventive concept, a high electron mobility transistor includes a first semiconductor layer on a substrate, a second semiconductor layer on the first semiconductor layer, a source electrode provided on one side of the second semiconductor layer, a drain electrode provided on the other side of the second semiconductor layer, a gate electrode provided on the second semiconductor layer between the source electrode and the drain electrode, a first protection film provided on a portion of the second semiconductor layer outside the gate electrode, the source electrode, and the drain electrode, and a dielectric block provided on the first protection film and surrounding the gate electrode.

In an embodiment, the high electron mobility transistor may further include a source pad, a drain pad, and a gate pad that are respectively provided on the source electrode, the drain electrode, and the gate electrode, and a second protection film provided on the first protection film, the dielectric block, the source pad, the drain pad, and the gate pad.

In an embodiment, the high electron mobility transistor may further include cavity filters provided on the second protection film and surrounding the gate electrode and the gate pad.

In an embodiment, the cavity filters may include an external cavity filter surrounding the dielectric block, and an internal cavity filter provided on the external cavity filter and surrounding the second protection film between the dielectric block and the gate pad.

In an embodiment, the high electron mobility transistor may further include an air pocket provided between the internal cavity filter and the second protection film.

In an embodiment of the inventive concept, a manufacturing method of a high electron mobility transistor includes forming a semiconductor layer on a substrate, forming a source electrode and a drain electrode on both sides of the semiconductor layer, respectively, forming a first protection film on a portion of the semiconductor layer, the source electrode, and the drain electrode, forming a dielectric block provided on the first protection film between the source electrode and the drain electrode and having an opening exposing a portion of the first protection film, exposing the semiconductor layer by removing the first protection film within the opening of the dielectric block, and forming a gate electrode and a gate pad within the opening of the dielectric block.

In an embodiment, the manufacturing method may further include forming a source pad and a drain pad on the source electrode and the drain electrode, respectively.

In an embodiment, the manufacturing method may further include forming a second protection film on the first protection film, the dielectric block, the source pad, the drain pad, the gate electrode, and the gate pad.

In an embodiment, the manufacturing method may further include forming cavity filters on the second protection film around the gate electrode.

In an embodiment, the cavity filters may include an external cavity filter provided on the second protection film outside the dielectric block, and an internal cavity filter provided within the external cavity filter and forming an air pocket with respect to the second protection film between the gate pad and the dielectric block.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

In the drawings:

FIG. 1 is a cross-sectional view showing an example of a high electron mobility transistor according to the concept of an embodiment of the inventive concept;

FIGS. 2 to 10 are cross-sectional views of processes illustrating the manufacturing method of the high electron mobility transistor according to an embodiment of the inventive concept;

FIG. 11 is a cross-sectional view illustrating an example of a high electron mobility transistor according to the concept of an embodiment of the inventive concept;

FIG. 12 is a cross-sectional view illustrating an example of a high electron mobility transistor according to the concept of an embodiment of the inventive concept;

FIG. 13 is a cross-sectional view illustrating an example of a high electron mobility transistor according to the concept of an embodiment of the inventive concept;

FIG. 14 is a plan view illustrating an example of a high electron mobility transistor according to the concept of an embodiment of the inventive concept; and

FIG. 15 is a cross-sectional view taken along line I-I′ of FIG. 14.

### DETAILED DESCRIPTION

In order to fully understand a configuration and effect of the technical idea of an embodiment of the inventive concept, preferred embodiments of the technical idea of the embodiment of the inventive concept will be described with reference to the accompanying drawings. However, the technical idea of the embodiment of the inventive concept is not limited to the embodiments disclosed below and may be implemented in various forms and various changes may be made thereto. However, the embodiments introduced herein are provided so that the disclosure of the technical idea of the embodiment of the inventive concept will be thorough and complete and will fully convey the scope of the embodiment of the inventive concept to those skilled in the art.

Parts indicated by the same reference numerals refer to the same components throughout the specification. The embodiments described in this specification will be described with reference to cross-sectional views and/or plan views, which are ideal illustrations of the embodiment of the inventive concept. In the drawings, the thicknesses of regions are exaggerated for effective description of technical content. Accordingly, the regions illustrated in the drawings have schematic properties, and shapes of the regions illustrated in the drawings are intended to illustrate a specific shape of the region of the device and are not intended to limit the scope of the embodiment of the inventive concept. Although various terms are used to describe various components in various embodiments of the embodiment of the inventive concept, these components should not be limited by these terms. These terms are merely used to distinguish one component from another. The embodiments described and illustrated herein also include complementary embodiments thereof.

The terms used in this specification are for describing the embodiments and are not intended to limit the embodiment of the inventive concept. In this specification, a singular form includes a plural form unless specifically stated otherwise in the context. The component referred to in terms “comprises” and/or “comprising” as used in the specification do not preclude the existence or addition of a referenced component, or one or more other components.

Hereinafter, an embodiment of the inventive concept will be described in detail by describing preferred embodiments of the technical idea of the embodiment of the inventive concept with reference to the accompanying drawings.

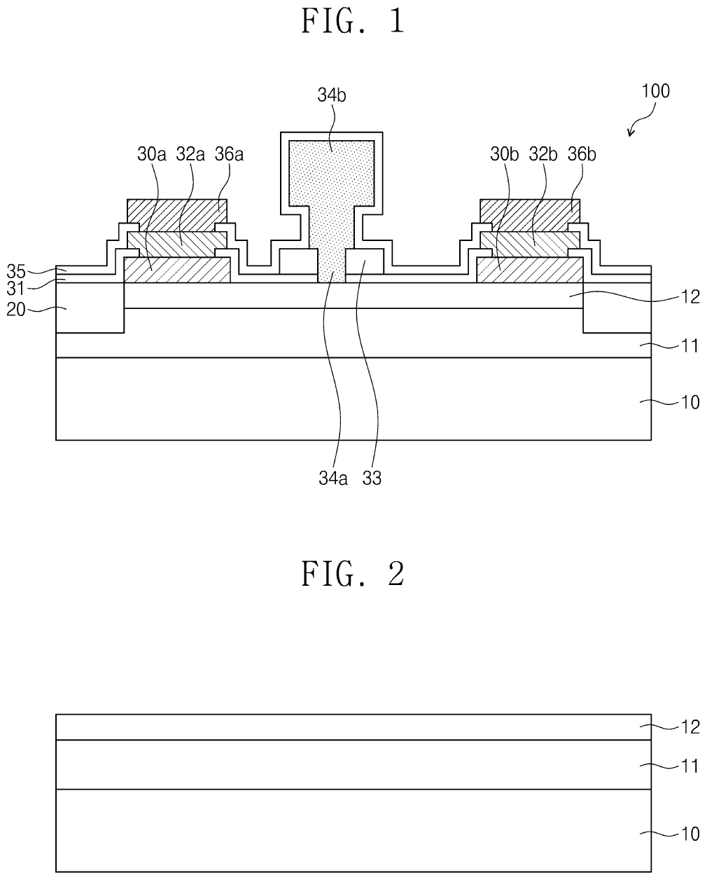

FIG. 1 illustrates an example of a high electron mobility transistor 100 according to the concept of an embodiment of the inventive concept.

Referring to FIG. 1, the high electron mobility transistor 100 of an embodiment of the inventive concept may include a nitride-based high electron mobility transistor. According to an example, the high electron mobility transistor 100 of the embodiment of the inventive concept includes a substrate 10, a first semiconductor layer 11, a second semiconductor layer 12, a source electrode 30a, a drain electrode 30b, and a first protection film 31, a gate electrode 34a, a dielectric block 33, and a second protection film 35.

The substrate 10 may contain silicon carbide (SiC), silicon (Si), gallium nitride (GaN), or diamond.

The first semiconductor layer 11 may be provided on the substrate 10. The first semiconductor layer 11 may contain a Group III-V semiconductor compound. For example, the first semiconductor layer 11 may contain AlN, InN, GaN, AlGaN, InGaN, AlInN, InAlGaN, etc. However, the first semiconductor layer 11 is not limited thereto, and the first semiconductor layer 11 may be made of a material other than the materials described above as long as it is made of a material capable of forming 2DEG therein. The first semiconductor layer 11 may be an undoped layer, but in some cases, it may be a layer to which predetermined impurities have been added. Although not illustrated, a transition layer may be provided between the substrate 10 and the first semiconductor layer 11. The transition layer may be a layer that alleviates a difference in lattice constant and thermal expansion coefficient between the substrate 10 and the first semiconductor layer 11.

The second semiconductor layer 12 is in contact with the first semiconductor layer 11 and forms a heterojunction with the first semiconductor layer 11. The second semiconductor layer 12 has a wider band gap than that of the first semiconductor layer 11 and may contain semiconductor materials having different lattice constants. The second semiconductor layer 12 may have a single-layer or multi-layer structure containing one or more materials selected from nitrides containing at least one of Al, Ga, In, and B. For example, the second semiconductor layer 12 may contain at least one of AlGaN, AlN, InAlN, InGaN, and InAlGaN and have a single-layer or layered structure. The second semiconductor layer 12 may be an undoped layer, but in some cases, it may be a layer to which predetermined impurities have been added. Polarization may occur due to the heterojunction structure of the first semiconductor layer 11 and the second semiconductor layer 12, thereby creating a two-dimensional electron gas (2DEG) region in the first semiconductor layer 11. The 2DEG may be used as a channel in the high electron mobility transistor. Although not illustrated, an insertion layer of several nanometers may be formed between the first semiconductor layer 11 and the second semiconductor layer 12. The insertion layer may be of AlN and may improve the mobility of the 2DEG by improving characteristics of the interface between the first semiconductor layer 11 and the second semiconductor layer 12.

A separation film 20 may be provided on the outside of the second semiconductor layer 12 at the edge of the first semiconductor layer 11. According to one example, the separation film 20 may include a shallow trench isolation (STI) region. For example, the separation film 20 may contain silicon oxide, silicon nitride, or silicon oxynitride.

The source electrode 30a may be provided on one side of the second semiconductor layer 12. The source electrode 30a may be provided adjacent to the separation film 20.

The drain electrode 30b may be provided on the other side of the second semiconductor layer 12. The drain electrode 30b may be provided adjacent to the separation film 20.

The first protection film 31 may be provided on a portion of the second semiconductor layer 12, the source electrode 30a, and the drain electrode 30b. The first protection film 31 may selectively expose the center of each of the source electrode 30a, the drain electrode 30b, and the second semiconductor layer 12.

The gate electrode 34a may be provided on the center of the second semiconductor layer 12. The gate electrode 34a may have a T-shape from a vertical perspective.

A gate pad 34b may be provided on the gate electrode 34a. The gate pad 34b may include a word line.

The dielectric block 33 may be provided around a bottom of the gate electrode 34a. The dielectric block 33 may be provided on the first protection film 31. The dielectric block 33 may reduce or minimize parasitic capacitance and fringing capacitance of the gate electrode 34a.

A source pad 32a may be provided on the source electrode 30a. A drain pad 32b may be provided on the drain electrode 30b.

The second protection film 35 may be provided on the first protection film 31, the source pad 32a, the drain pad 32b, the dielectric block 33, the gate electrode 34a, and the gate pad 34b. The second protection film 35 may selectively expose the center of each of the source pad 32a and the drain pad 32b.

A source wiring 36a and a drain wiring 36b may be provided on the source pad 32a and the drain pad 32b, respectively. The source wiring 36a and the drain wiring 36b may be provided on a portion of the second protection film 35.

Therefore, the high electron mobility transistor 100 of an embodiment of the inventive concept may reduce or minimize parasitic capacitance and fringing capacitance by using the dielectric block 33 surrounding the bottom of the gate electrode 34a.

A manufacturing method of the high electron mobility transistor 100 of an embodiment of the inventive concept configured as described above will be described as follows.

FIGS. 2 to 10 illustrate the manufacturing method of the high electron mobility transistor 100 of an embodiment of the inventive concept.

Referring to FIG. 2, the first semiconductor layer 11 and the second semiconductor layer 12 are formed on the substrate 10. The first semiconductor layer 11 may contain a Group III-V semiconductor compound formed by molecular beam epitaxy (MBE) or metal organic chemical vapor deposition (MOCVD).

The second semiconductor layer 12 may be provided on the first semiconductor layer 11 to form a heterojunction with the first semiconductor layer 11. For example, the second semiconductor layer 12 may contain at least one of AlGaN, AlN, InAlN, InGaN, and InAlGaN.

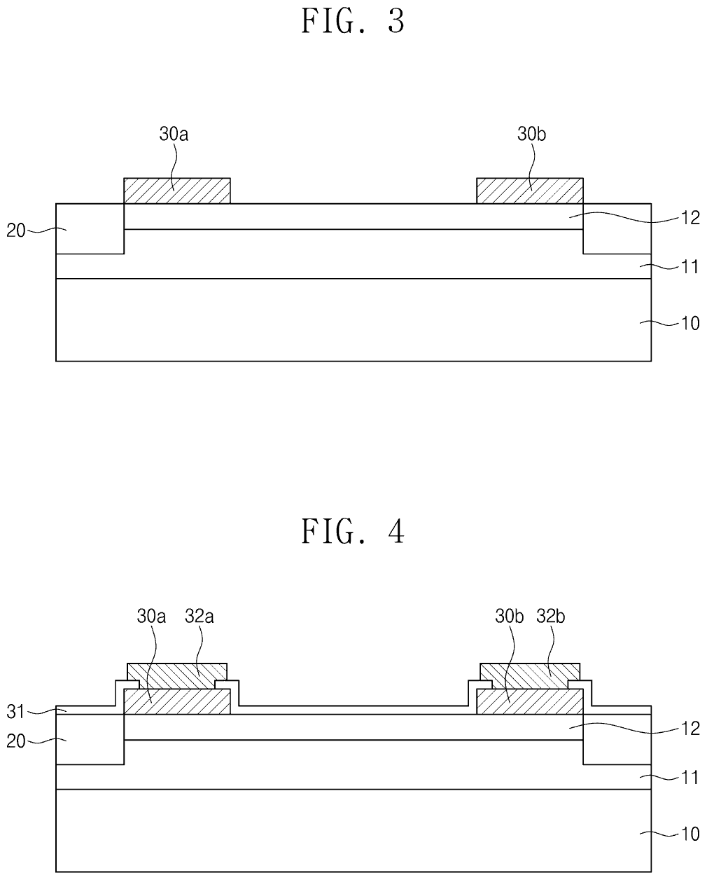

Referring to FIG. 3, the source electrode 30a and the drain electrode 30b are formed on one side and the other side of the second semiconductor layer 12, respectively. The source electrode 30a and the drain electrode 30b may be formed by a photolithography process, a metal deposition process, and a lift-off process. A photoresist pattern may be formed on the second semiconductor layer 12 by the photolithography process, and a metal thin film of Ti/Al/Ni/Au may be formed on the photoresist pattern and the second semiconductor layer 12 by an electron beam evaporator. A portion of the metal thin film and the photoresist pattern may be removed through the lift-off process to form the source electrode 30a and the drain electrode 30b. Alternatively, the source electrode 30a and the drain electrode 30b may be formed by the metal deposition process, the photolithography process, and an etching process, but the embodiment of the inventive concept is not limited thereto. The source electrode 30a and the drain electrode 30b may have ohmic properties through rapid heat treatment. During rapid heat treatment, the source electrode 30a and the drain electrode 30b come into contact with 2DEG, which is a semiconductor layer, and have ohmic properties.

The source electrode 30a and the drain electrode 30b may be formed and the separation film 20 may be formed. The separation film 20 may be formed by an ion implantation process or an etching process. The separation film 20 may separate the source electrode 30a and drain electrode 30b of adjacent devices.

Referring to FIG. 4, the first protection film 31, the source pad 32a, and the drain pad 32b are formed on the second semiconductor layer 12, the source electrode 30a, and the drain electrode 30b. The first protection film 31 may include a film of SiN, SiO₂, Al₂O₃, HfO₂, ZrO₂, or TiO₂, or a multilayer film, which contains SiN, SiO₂, Al₂O₃, HfO₂, ZrO₂, or TiO₂, that are formed through a plasma chemical vapor deposition (PECVD) process or an atomic layer deposition (ALD) process. The first protection film 31 is a passivation film that may prevent charges from being trapped on the surface of the second semiconductor layer, thereby preventing current reduction and current collapse phenomenon. The first protection film 31 may be removed from the source electrode 30a and the drain electrode 30b by a photolithography process and an etching process. The etching process may include a dry or wet etching process. The dry etching process may include an inductively coupled plasma etching (ICP) process using CF₄ gas as a source gas. The wet etching process may be performed by using buffered oxide etchant (BOE).

The source pad 32a and the drain pad 32b may be formed on the source electrode 30a and the drain electrode 30b exposed by the first protection film 31, respectively. The source pad 32a and drain pad 32b may be formed by the photolithography process, the metal deposition process, and the lift-off process. The source pad 32a and the drain pad 32b may contain multilayer metal containing at least one of Ti and Au.

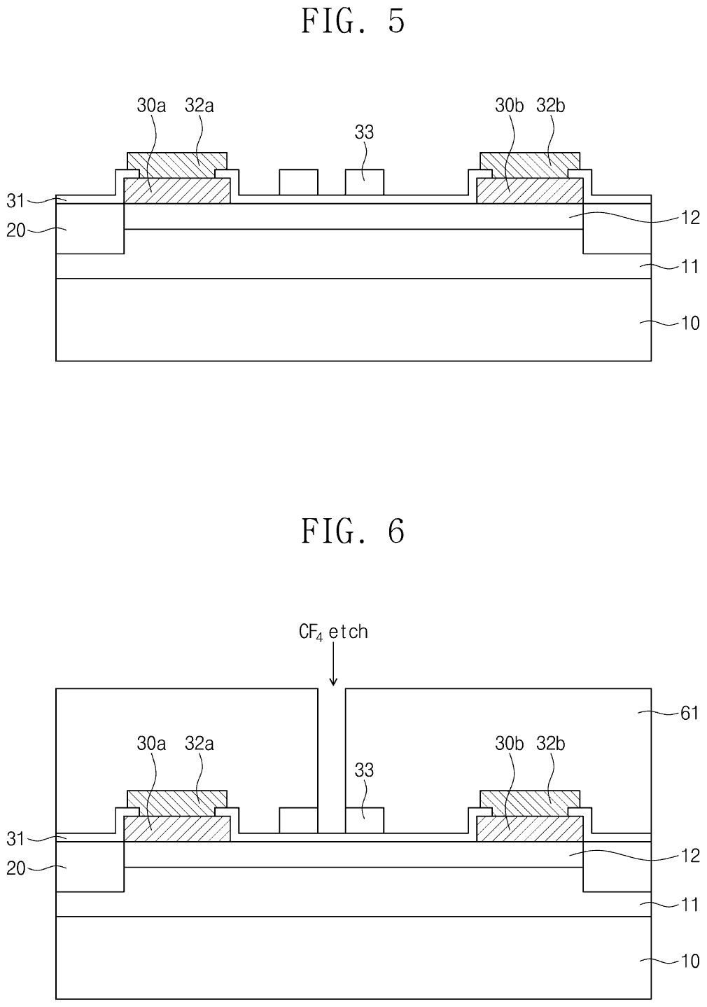

Referring to FIGS. 5 and 6, the dielectric block 33 is formed on the center of the first protection film 31 between the source pad 32a and the drain pad 32b. The dielectric block 33 may be formed closer to the source electrode 30a than the drain electrode 30b. For example, the dielectric block 33 may contain silicon oxide (SiO₂). Alternatively, the dielectric block 33 may contain silicon nitride (SiN), and the embodiment of the inventive concept is not limited thereto. The dielectric block 33 may be formed by a dielectric deposition process, the electron beam lithography process, and the etching process. Among the processes, the electron beam lithography process may include an electron beam lithography process using hydrogen silsesquioxane (HSQ) which is a negative electron beam resist.

Referring to FIG. 6, an opening of the dielectric block 33 may be formed by the electron beam lithography process and the etching process. A first PMMA resist pattern 61 may be formed on the dielectric block 33, the first protection film 31, the source pad 32a, and the drain pad 32b through the electron beam lithography process. The center of the dielectric block 33 exposed by the first PMMA resist pattern 61 may be removed through the dry etching process. An etching gas used in the dry etching process may include CF4. An opening may be formed in the center of the dielectric block 33. The opening in dielectric block 33 may define a gate length.

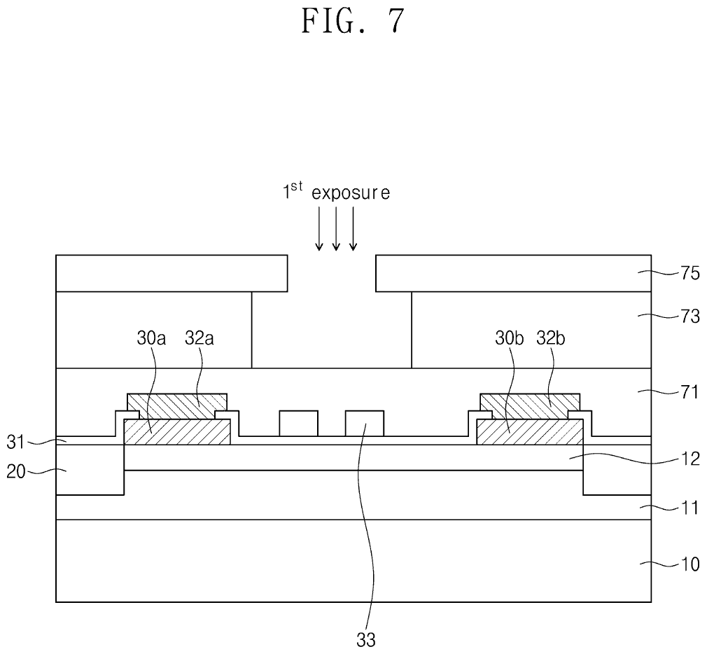

Referring to FIGS. 7 to 10, the gate electrode 34a and the gate pad 34b are formed inside and on the top of the dielectric block 33. A gate electrode 34a and the gate pad 34b may be formed through an electron beam lithography process, an etching process, and an e-beam deposition process. The first PMMA resist pattern 61 may be removed through a cleaning process.

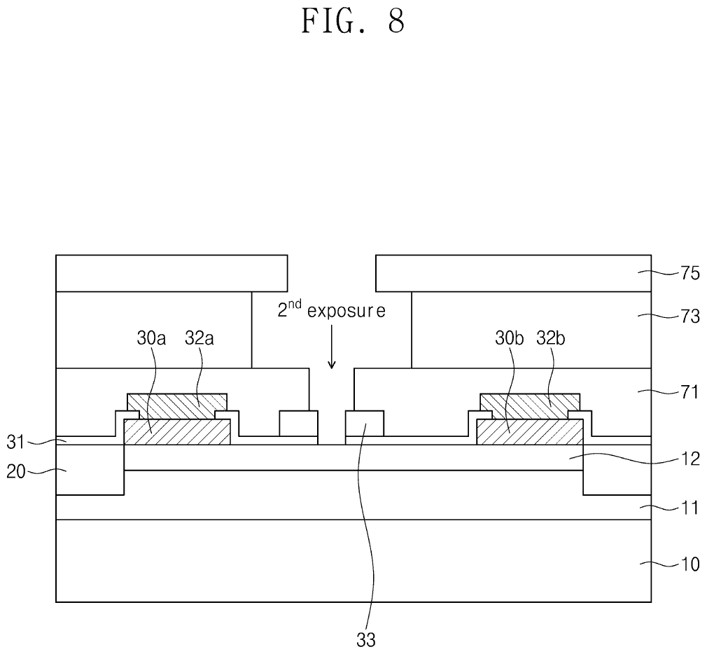

Referring to FIGS. 7 and 8, a second PMMA resist pattern 71, a copolymer pattern 73, and a PMMA pattern 75 may be formed through the electron beam lithography process. The electron beam exposure device may perform a primary exposure process on the copolymer pattern 73 and the PMMA pattern 75 and a secondary exposure process on the second PMMA resist pattern 71. The second PMMA resist pattern 71, the copolymer pattern 73, and the PMMA pattern 75 have a T-shape from a vertical perspective, and the dielectric block 33 and the first protection film 31 may be partially exposed. The first protection film 31 between the dielectric blocks 33 may be removed through an etching process. The second semiconductor layer 12 may be exposed through the first protection film 31, the dielectric block 33, the second PMMA resist pattern 71, the copolymer pattern 73, and the PMMA pattern 75.

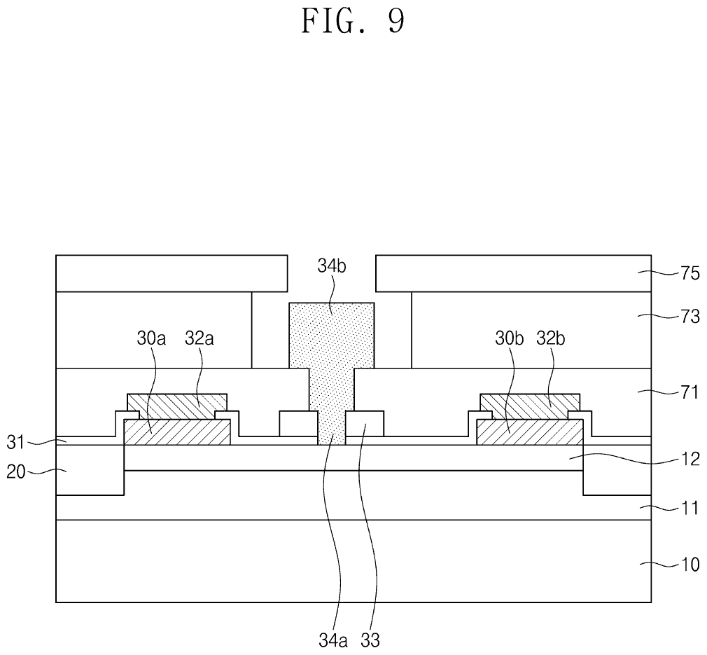

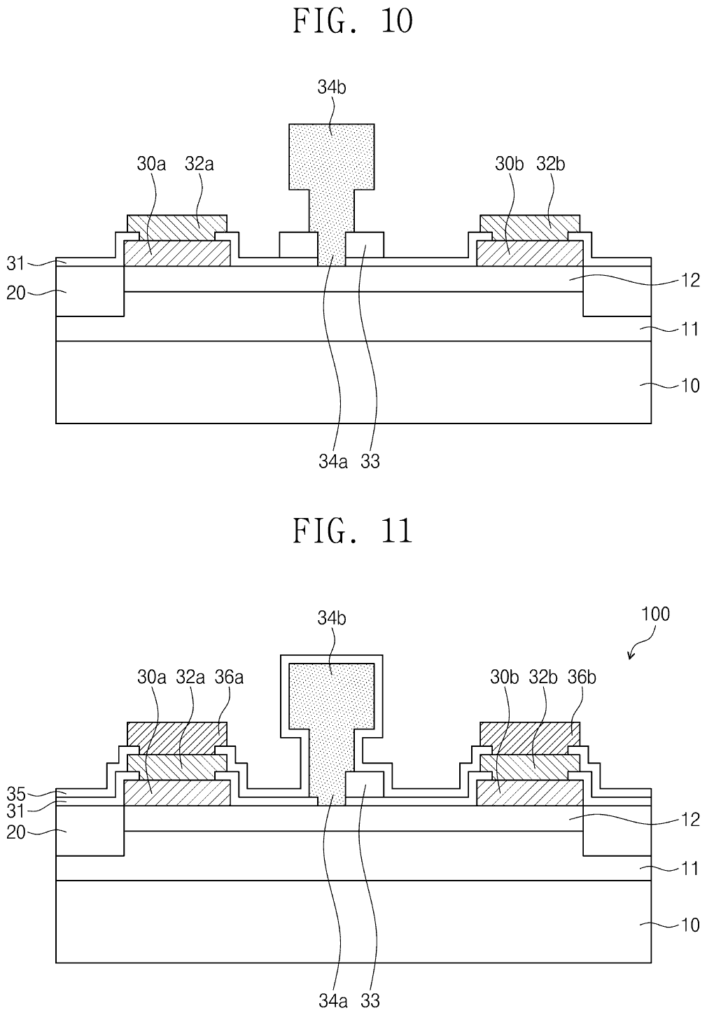

Referring to FIGS. 9 and 10, the gate electrode 34a and the gate pad 34b may be formed on the second semiconductor layer 12 exposed by the first protection film 31, the dielectric block 33, the second PMMA resist pattern 71, the copolymer pattern 73, and the PMMA pattern 75. The gate electrode 34a and gate pad 34b may be formed through the e-beam deposition process. The gate electrode 34a and gate pad 34b may have a T-shape from a vertical perspective. The gate pad 34b may be formed on the gate electrode 34a. The gate pad 34b may be wider or larger than the gate electrode 34a. The gate electrode 34a and gate pad 34b may contain Ni/Au or Pt/Au. The second PMMA resist pattern 71, the copolymer pattern 73, and the PMMA pattern 75 may be removed through the cleaning process. The dielectric block 33 may support the gate electrode 34a to form a wider gate pad 34b and reduce the resistance of the gate electrode 34a.

Referring to FIG. 1 again, the second protection film 35 is formed on the gate electrode 34a, the gate pad 34b, the first protection film 31, the source pad 32a, and the drain pad 32b. The second protection film 35 may include a film of SiN, SiO2, or SiON, or a multilayer film, which contains SiN, SiO2, and SiON, that are formed through the plasma chemical vapor deposition (PECVD) process or the atomic layer deposition (ALD) process. The second protection film 35 may serve as a passivation of a device and may include an insulating film used in a metal-insulating film-metal capacitor, which is a passive device of an integrated circuit.

Next, the second protection film 35 may be removed from the source pad 32a and the drain pad 32b through the photolithography process and the etching process. Among the processes, CF4 may be used as an etching gas in the etching process.

Then, a source wiring 36a and a drain wiring 36b may be formed on the source pad 32a and the drain pad 32b, respectively. The source wiring 36a and the drain wiring 36b may be formed through the photolithography process, the metal deposition process, and the lift-off process.

FIG. 11 illustrates an example of a high electron mobility transistor 100 according to the concept of an embodiment of the inventive concept.

Referring to FIG. 11, the dielectric block 33 of the high electron mobility transistor 100 of an embodiment of the inventive concept may be selectively provided between the gate electrode 34a and the drain electrode 30b. The dielectric block 33 may be removed between the gate electrode 34a and the source electrode 30a.

The substrate 10, the first semiconductor layer 11, the second semiconductor layer 12, the source electrode 30a, the drain electrode 30b, the first protection film 31, the source pad 32a, the drain pad 32b, the gate electrode 34a, the gate pad 34b, the second protection film 35, the source wiring 36a, and the drain wiring 36 may be configured in the same way as in FIG. 1.

FIG. 12 illustrates an example of a high electron mobility transistor 100 according to the concept of an embodiment of the inventive concept.

Referring to FIG. 12, the dielectric block 33 of the high electron mobility transistor 100 of an embodiment of the inventive concept may contact the second semiconductor layer 12 without the first protection film 31.

The substrate 10, the first semiconductor layer 11, the second

semiconductor layer 12, the source electrode 30a, the drain electrode 30b, the first protection film 31, the source pad 32a, the drain pad 32b, the gate electrode 34a, the gate pad 34b, the second protection film 35, the source wiring 36a, and the drain wiring 36 may be configured in the same way as in FIG. 1.

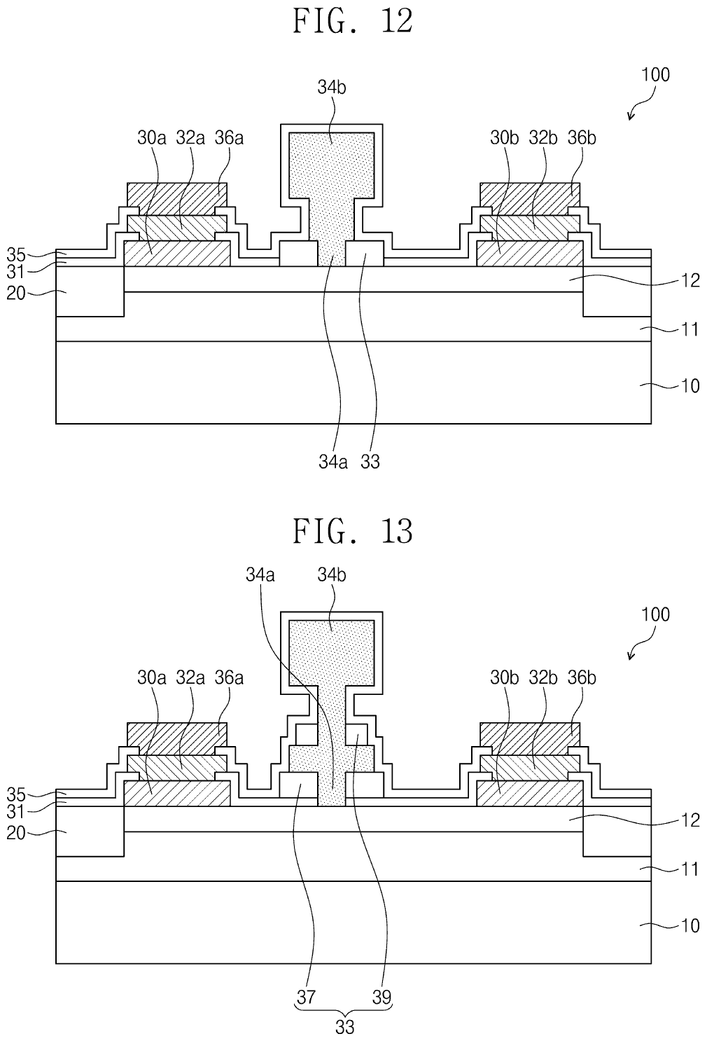

FIG. 13 illustrates an example of a high electron mobility transistor 100 according to the concept of an embodiment of the inventive concept.

Referring to FIG. 13, the dielectric block 33 of the high electron mobility transistor 100 of an embodiment of the inventive concept may include a lower dielectric block 37 and an upper dielectric block 39. For example, each of the lower dielectric block 37 and the upper dielectric block 39 may contain silicon oxide (SiO₂). The lower dielectric block 37 may surround the bottom of the gate electrode 34a between the first protection film 31 and the second protection film 35.

The upper dielectric block 39 may be provided on the lower dielectric block 37 and the gate electrode 34a. The upper dielectric block 39 may be provided between the gate electrode 34a and the second protection film 35. The upper dielectric block 39 may have a width that is smaller or narrower than the width of the lower dielectric block 37. The lower dielectric block 37 may be larger or wider than the upper dielectric block 39.

The gate electrode 34a may be provided between the lower dielectric block 37 and the upper dielectric block 39. The gate electrode 34a may separate the dielectric block 33 and the upper dielectric block 39. The gate electrode 34a may have a+ shape from a vertical perspective. The upper dielectric block 39 may be narrower or smaller than the dielectric block 33. The gate electrode 34a between the lower dielectric block 37 and the upper dielectric block 39 may have a width equal to a width of the gate pad 34b. The lower dielectric block 37, gate electrode 34a, and upper dielectric block 39 may become narrower or smaller as their height increases.

The substrate 10, the first semiconductor layer 11, the second semiconductor layer 12, the source electrode 30a, the drain electrode 30b, the first protection film 31, the source pad 32a, the drain pad 32b, the gate electrode 34a, the gate pad 34b, the second protection film 35, the source wiring 36a, and the drain wiring 36 may be configured in the same way as in FIG. 1.

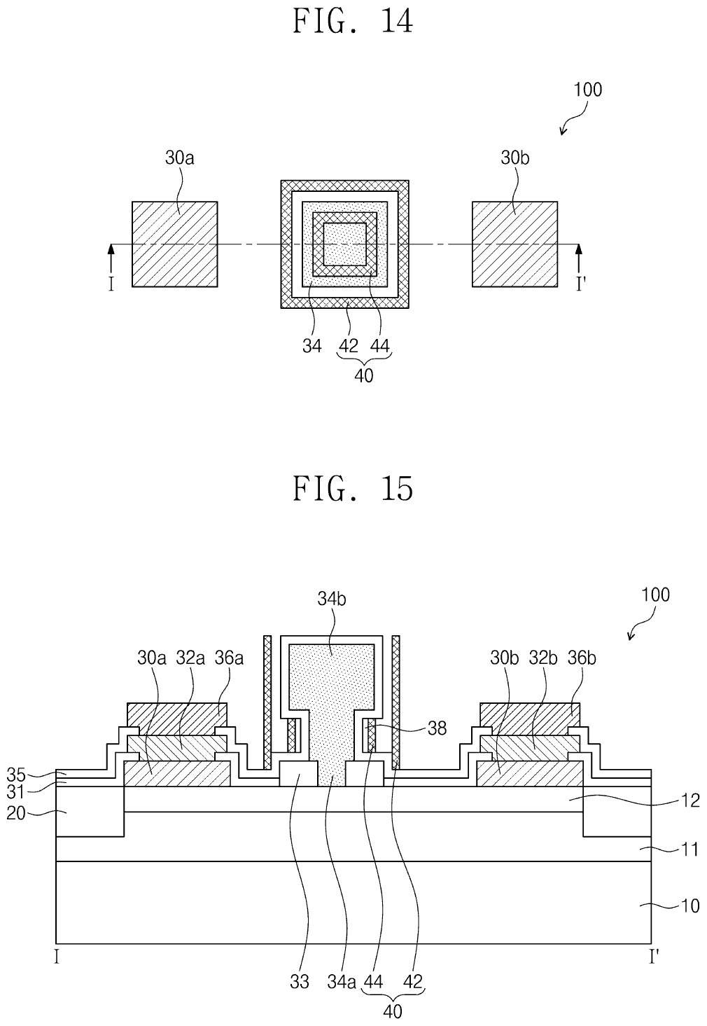

FIG. 14 illustrates an example of a high electron mobility transistor 100 according to the concept of an embodiment of the inventive concept. FIG. 15 illustrates a cross section taken along line I-I′ of FIG. 14.

Referring to FIGS. 14 and 15, the high electron mobility transistor 100 of an embodiment of the inventive concept may further include cavity filters 40. The cavity filters 40 may surround the gate electrode 34a and the gate pad 34b. For example, the cavity filters 40 may contain metal containing at least one of gold (Au), silver (Ag), aluminum (Al), tungsten (W), or nickel (Ni). The cavity filters 40 may be grounded or floating. The cavity filters 40 may reduce or minimize parasitic capacitance and fringing capacitance of the gate electrode 34a. Each of the cavity filters 40 may have a square shape in plan view. Alternatively, each of the cavity filters 40 may have a circular or ring shape, but the embodiment of the inventive concept is not limited thereto.

According to one example, the cavity filters 40 may include an external cavity filter 42 and an internal cavity filter 44.

The external cavity filter 42 may be provided on the first protection film 31 and the second protection film 35. The external cavity filter 42 may surround the dielectric block 33, the gate electrode 34a, and the gate pad 34b. The external cavity filter 42 may be provided outside the internal cavity filter 44. The outer cavity filter 42 may be thicker than the inner cavity filter 44 from a vertical perspective. The outer cavity filter 42 may be wider than the inner cavity filter 44 in plan view.

The internal cavity filter 44 may be provided within the external cavity filter 42. The inner cavity filter 44 may be thinner than the outer cavity filter 42. The internal cavity filter 44 may be provided between the dielectric block 33 and the gate pad 34b. The internal cavity filter 44 may surround the second protection film 35 between the dielectric block 33 and the gate pad 34b and the gate electrode 34a.

An air pocket 38 may be provided between the internal cavity filter 44 and the second protection film 35. The air pocket 38 may include an empty space between the second protection film 35 outside the gate electrode 34a and the internal cavity filter 44. The air pocket 38 may be provided around the second protection film 35 between the dielectric block 33 and the gate pad 34b. The air pocket 38 reduces the dielectric constant between the gate electrode 34a and the source electrode 30a and between the gate electrode 34a and the drain electrode 30b, thereby reducing or minimizing the parasitic capacitance and fringing capacitance.

The substrate 10, the first semiconductor layer 11, the second semiconductor layer 12, the source electrode 30a, the drain electrode 30b, the first protection film 31, the source pad 32a, the drain pad 32b, the gate electrode 34a, the gate pad 34b, the second protection film 35, the source wiring 36a, and the drain wiring 36 may be configured in the same way as in FIG. 1.

The high electron mobility transistor according to an embodiment of the inventive concept may reduce parasitic capacitance and fringing capacitance by using the dielectric block surrounding the bottom of the gate electrode

As above, although embodiments of the inventive concept have been described with reference to the accompanying drawings, those of ordinary skill in the technical field to which the embodiment of the inventive concept pertains will understand that the embodiment of the inventive concept may be implemented in other specific forms without changing its technical spirit or essential features. Therefore, the embodiments described above should be understood in all respects as illustrative and not restrictive.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A high electron mobility transistor comprising:
a semiconductor layer on a substrate;
a source electrode and a drain electrode on both sides of the semiconductor layer;
a gate electrode provided on the semiconductor layer between the source electrode and the drain electrode; and
a dielectric block surrounding a bottom of the gate electrode.

2. The high electron mobility transistor of claim 1, wherein
the dielectric block includes
a lower dielectric block, and
an upper dielectric block provided on the lower dielectric block.

3. The high electron mobility transistor of claim 2, wherein
the lower dielectric block is wider than the upper dielectric block.

4. The high electron mobility transistor of claim 2, further comprising:
a gate pad provided on the gate electrode, wherein
the gate electrode has a width equal to a width of the gate pad between the lower dielectric block and the upper dielectric block.

5. The high electron mobility transistor of claim 4, further comprising:
cavity filters provided on the dielectric block.

6. The high electron mobility transistor of claim 5, wherein
the cavity filters include
an external cavity filter surrounding the dielectric block and the gate pad, and
an internal cavity filter provided within the external cavity filter.

7. The high electron mobility transistor of claim 6, wherein
each of the external cavity filter and the internal cavity filter has a square ring shape.

8. The high electron mobility transistor of claim 6, wherein
the external cavity filter is higher or thicker than the internal cavity filter.

9. The high electron mobility transistor of claim 6, wherein
the internal cavity filter is provided between the gate pad and the dielectric block.

10. The high electron mobility transistor of claim 5, further comprising:
a protection film between the dielectric block and the semiconductor layer.

11. A high electron mobility transistor comprising:
a first semiconductor layer on a substrate;
a second semiconductor layer on the first semiconductor layer;
a source electrode provided on one side of the second semiconductor layer;
a drain electrode provided on the other side of the second semiconductor layer;
a gate electrode provided on the second semiconductor layer between the source electrode and the drain electrode;
a first protection film provided on a portion of the second semiconductor layer outside the gate electrode, the source electrode, and the drain electrode; and
a dielectric block provided on the first protection film and surrounding the gate electrode.

12. The high electron mobility transistor of claim 11, further comprising:
a source pad, a drain pad, and a gate pad that are respectively provided on the source electrode, the drain electrode, and the gate electrode; and
a second protection film provided on the first protection film, the dielectric block, the source pad, the drain pad, and the gate pad.

13. The high electron mobility transistor of claim 12, further comprising:
cavity filters provided on the second protection film and surrounding the gate electrode and the gate pad.

14. The high electron mobility transistor of claim 13, wherein
the cavity filters include
an external cavity filter surrounding the dielectric block, and
an internal cavity filter provided on the external cavity filter and surrounding the second protection film between the dielectric block and the gate pad.

15. The high electron mobility transistor of claim 14, further comprising:
an air pocket provided between the internal cavity filter and the second protection film.

16. A manufacturing method of a high electron mobility transistor, the manufacturing method comprising:
forming a semiconductor layer on a substrate;
forming a source electrode and a drain electrode on both sides of the semiconductor layer, respectively;
forming a first protection film on a portion of the semiconductor layer, the source electrode, and the drain electrode;
forming a dielectric block provided on the first protection film between the source electrode and the drain electrode and having an opening exposing a portion of the first protection film;
exposing the semiconductor layer by removing the first protection film within the opening of the dielectric block; and
forming a gate electrode and a gate pad within the opening of the dielectric block.

17. The manufacturing method of claim 16, further comprising:
forming a source pad and a drain pad on the source electrode and the drain electrode, respectively.

18. The manufacturing method of claim 17, further comprising:
forming a second protection film on the first protection film, the dielectric block, the source pad, the drain pad, the gate electrode, and the gate pad.

19. The manufacturing method of claim 18, further comprising:
forming cavity filters on the second protection film around the gate electrode.

20. The manufacturing method of claim 19, wherein
the cavity filters include
an external cavity filter provided on the second protection film outside the dielectric block, and
an internal cavity filter provided within the external cavity filter and forming an air pocket with respect to the second protection film between the gate pad and the dielectric block.
